(19) United States
(12) Patent Application Publication
(10) Pub. No.: US 2012/0086450 A1
(43) Pub. Date: Apr. 12, 2012

(54) ENHANCED SECURITY PORTAL WITH MULTIPLE SENSORS

(76) Inventors: Christopher W. Crowley, San Diego, CA (US); Erik E. Magnuson, Cardiff, CA (US)

(21) Appl. No.: 13/243,395

(22) Filed: Sep. 23, 2011

Related U.S. Application Data
(60) Provisional application No. 61/390,763, filed on Oct. 7, 2010.

(51) Int. Cl. G01R 33/34; G01R 33/48

(52) U.S. Cl. 324/315; 324/322

(57) ABSTRACT

A system and method for detecting objects foreign to a human body. The system including a thermal detector configured to obtain thermal imaging data, a quadrapole resonance (QR) device configured to transmit an excitation signal and receive a resulting signal emanating from a material excited by the excitation signal, and a controller configured to determine if a foreign object is present based on the thermal imaging data and the excitation signal.

### CROSS-REFERENCE TO RELATED APPLICATIONS

This application claims priority to Provisional Patent Application No. 61/390,763 filed Oct. 7, 2010, which is hereby incorporated by reference in its entirety.

### BACKGROUND OF THE INVENTION

The embodiments described herein relate generally to inspection systems used to inspect a person and, more particularly, to an inspection system configured to inspect a person for a target material.

The Transportation Security Administration (TSA) has recently mandated more stringent inspection procedures be implemented by the travel industry to reduce the possibility of passengers boarding a carrier, such as an aircraft, carrying contraband, such as concealed weapons, explosives, and/or other contraband. To facilitate preventing passengers boarding a carrier carrying contraband, the TSA requires that all passengers be screened and/or inspected prior to boarding the carrier.

In at least some known inspection systems, passengers arriving at an airport terminal, for example, are examined by a trace detection system that includes a “puffer.” The puffer uses a high-power puff of air to dislodge particles from a person. The trace detection systems detect and analyze the particles to determine if the person has been in proximity to contraband items. However, such systems may not detect a contraband item that is concealed beneath multiple layers of clothing or inside a body cavity. In addition, the air puffs can be disturbing to some passengers and can result in contaminants being introduced into the detection system, which can increase service and cleaning costs. Contamination can also cause excessive system downtime during service calls and cleaning.

Moreover, in at least some known inspection systems, passengers are subjected to whole body imaging. Whole body imaging systems may include X-ray backscatter (XRB) systems and millimeter-wave (MMW) systems, such as active MMW systems and passive MMW systems. These systems provide an image of articles that may be hidden under clothing. However, the ability of whole body imaging systems to identify contraband hidden between a passenger's legs or within a passenger's body cavity may be limited. These limitations may be exacerbated by the use of privacy filters that can obscure the groin area in an image. In addition, it is possible that a contraband item may be shaped to resemble body parts. Processing of imaging data is also time-consuming and requires an operator to view an image to detect contraband or a possibility of contraband.

Furthermore, at least some known inspection systems include nuclear quadrupole resonance (NQR) sensors that detect contraband in or on the passenger's shoes, socks, or other articles of clothing in proximity to the sensors. However, such systems are configured to detect only some contraband for which the systems are designed or configured.

### BRIEF DESCRIPTION OF THE INVENTION

In one aspect, a method for detecting objects foreign to a human body using an inspecting system including a controller, a thermal detector, and a quadrapole resonance (QR) device is provided. The method includes obtaining thermal imaging data from the thermal detector, transmitting an excitation signal by the QR device, and determining if a foreign object is present based on the thermal imaging data and whether a resulting signal that emanated from a material excited by the excitation signal is received by the QR device.

In another aspect, a system for detecting objects foreign to a human body is provided. The system includes a thermal detector configured to obtain thermal imaging data, a quadrapole resonance (QR) device configured to transmit an excitation signal and receive a resulting signal that emanated from a material excited by the excitation signal, and a controller configured to determine if a foreign object is present based on the thermal imaging data and the excitation signal.

In another aspect, One or more computer-readable storage media having computer-executable instructions embodied thereon is provided. The computer-executable instructions, when executed by at least one processor cause at least one processor to obtain thermal imaging data from a thermal detector, transmit an excitation signal by a QR device, and determine if a foreign object is present based on the thermal imaging data and whether a resulting signal that emanated from a material excited by the excitation signal is received by the QR device.

### BRIEF DESCRIPTION OF THE DRAWINGS

FIG. 1 is a block diagram of an exemplary inspection system for use in inspecting a passenger for contraband.

FIG. 2 is a top view of an exemplary thermal detection system that may be used with the inspection system shown in FIG. 1.

FIG. 3 is a side view of the thermal detection system shown in FIG. 2.

FIG. 4 is a top view of an exemplary quadrupole resonance (QR) system that may be used with the inspection system shown in FIG. 1.

FIG. 5 is a side view of the QR system shown in FIG. 4.

FIG. 6 is a perspective view of the inspection system shown in FIG. 1.

### DETAILED DESCRIPTION OF THE INVENTION

Exemplary embodiments of inspection systems are described herein for use in inspecting a passenger for contraband. The contraband may be approximately the same temperature as the passenger's body or may have a different temperature from the passenger's body. Moreover, the contraband may be closely held to the passenger's body, loosely held away from the passenger's body, or may be held within the passenger's body, such as within a body cavity. Furthermore, the inspection systems described herein are configured to inspect a passenger along the entire height of the passenger. The data collected by the subsystems described herein is combined by a controller to identify a location and/or a probability of a chemical composition of the contraband. As used herein, the term “contraband” refers to illegal substances, explosives, narcotics, weapons, a threat object, and/or any other material that a person is not allowed to possess in a restricted area, such as in an airport or on an airplane.

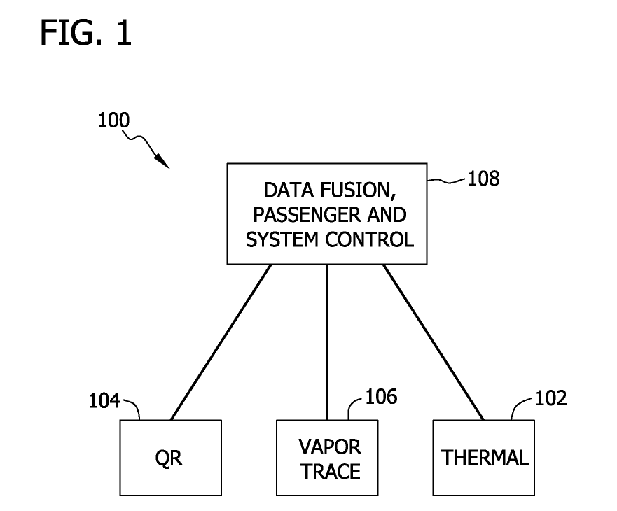

FIG. 1 is a block diagram of an inspection system 100 for use in inspecting a passenger for contraband. Inspection system 100 includes a plurality of detection systems, such as a thermal detection system 102, a quadrupole resonance (QR) system 104, and a trace sensor 106. In the exemplary embodiment, inspection system 100 includes only QR system 104 and thermal detection system 102. In an alternative embodiment, inspection system 100 includes thermal detection system 102, QR system 104, and trace sensor 106. Further alternative embodiments of inspection system 100 may also include other sensors including, but not limited to, a QR-based shoe scanner and/or a metal detector. However, it should be understood that the embodiments described herein enable a passenger to be scanned using a single pass. In the exemplary embodiment, inspection system 100 also includes a controller 108 that is communicatively and/or operatively coupled to thermal detection system 102, QR system 104, and trace sensor 106 via a network, for example. Controller 108 communicates with each detection subsystem 102, 104, and 106 to facilitate controlling an order and/or timing of inspection by each detection subsystem 102, 104, and 106. For example, controller 108 may cause thermal detection system 102 to perform a scan, followed by QR system 104, and then trace sensor 106. Alternatively, controller 108 may cause each detection subsystem 102, 104, and 106 to substantially simultaneously inspect the passenger to facilitate an enhanced throughput of inspection system 100.

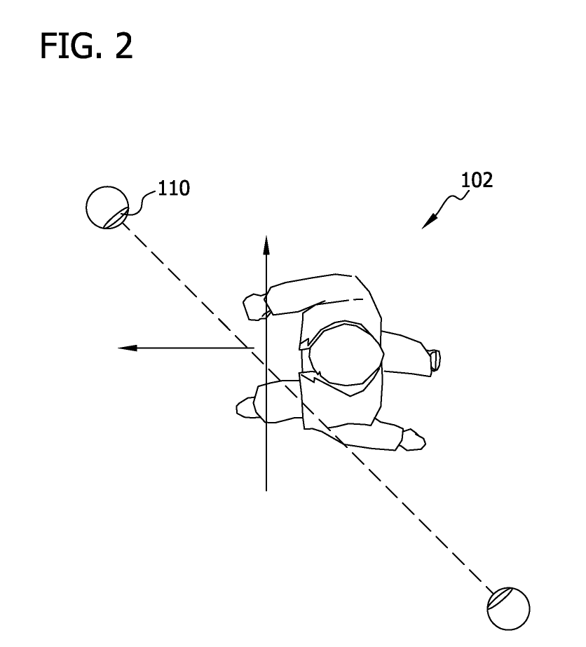

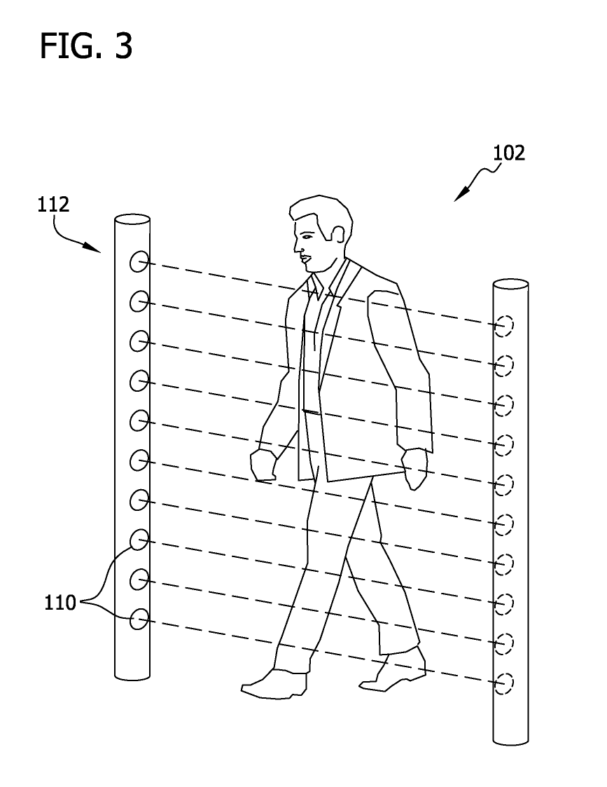

FIGS. 2 and 3 are views of thermal detection system 102. Specifically, FIG. 2 is a top view of thermal detection system 102, and FIG. 3 is a side view of thermal detection system 102. In the exemplary embodiment, thermal detection system 102 includes one or more sensors 110. In some embodiments, thermal detection system 102 includes one or more arrays 112 of sensors 110. In one embodiment, sensor array 112 may be scanned across the passenger by rotating sensor array 112, translating sensor array 112, or by a combination of rotating and translating sensor array 112. In the exemplary embodiment, thermal detection system 102 is configured to use thermal imaging to distinguish the thermal properties of contraband from thermal properties of a passenger. Moreover, thermal detection system 102 is a passive millimeter wave imaging system. Millimeter waves are naturally emitted from the body, exhibit good temperature contrast, and are attenuated less by clothing than infrared (IR) waves. In the exemplary embodiment, thermal detection system 102 detects waves with the frequency of approximately 94 gigahertz (GHz). Alternative embodiments may use other frequencies in the range between approximately 20 GHz and approximately 3 terahertz (THz). More specifically, thermal detection system 102 may use frequencies in the range between approximately 77 GHz and approximately 24 GHz.

In the exemplary embodiment, thermal detection system 102 is configured to discern bulk articles that are not in thermal equilibrium with the passenger's body, in particular, articles that are not thermally bound to the body. Such articles could include articles in a pocket or bulky, volumetric articles, where it is not possible for the entire bulk of the article to be in contact with the body. While described primarily as a sensor for identifying thermally contrasting articles, it should be understood that articles that are in tight thermal contact with the body may also be detected, including those articles having emissivities different from that of the body, as well as articles with high reflectivities and/or low transmissivities. Such articles could include ceramic and metal weapons, for example.

In some embodiments, thermal detection system 102 includes a processor and a memory area coupled to the processor (neither shown). The memory area is configured to store a two-dimensional or three-dimensional map of the measured thermal distributions, and the processor is configured to generate a thermal image based on the stored map. In the exemplary embodiment, however, thermal detection system 102 does not form an image. Rather, the processor analyzes the stored map to determine whether the presence of contraband is suspected, and generates an alarm when contraband in such a case is suspected. As such, thermal detection system 102 is less prone to privacy concerns, in part because the expected resolution is low enough that private parts are not distinguishable. Accordingly, thermal detection system 102 is tuned, configured, and adapted to enhance its ability to quickly deliver an identification of the thermally-contrast articles. The tuning, configuring, or adaptation may include configuring thermal detection system 102 for operation in a thermal resolution range and/or at a particular spatial resolution, and/or enabling the processor to automatically analyze the data collected by sensors 110 and/or sensor arrays 112.

In some embodiments, thermal detection system 102 is configured to operate at a range of thermal resolution that is lower than the resolution used by similar systems that are known in the art. For example, earlier systems used thermal resolutions of less than approximately 1° C. However, the thermal resolution for thermal detection system 102 may be simplified to identify only those articles that are thermally distinct, as distinguished by a resolution of greater than approximately 1° C. In the exemplary embodiment, the required resolution would be to identify those articles that are at least 3° C. cooler than the passenger's body.

In some embodiments, thermal detection system 102 is configured to operate at a lower spatial resolution, to more quickly identify bulk threats offset from the passenger's body, without requiring image detail such as edges. For example, if there is a blob of material colder than the body, then the material has been identified, regardless of the resolution. In the exemplary embodiment, the required spatial resolution would be at least 2 centimeters (cm). However, the spatial resolution may be more or less than approximately 2 cm.

In some embodiments, thermal detection system 102 is configured for automatic operation with computer-aided analysis. To facilitate finding contraband that is in thermal contrast with the passenger's body, computer-aided threat recognition is possible with an algorithm that first sifts the image for articles that contrast with the passenger's body and its associated temperature. If the total quantity of sifted material exceeds a threshold, then an alarm could be automatically initiated, without requiring security personnel to view an image. In the exemplary embodiment, an article having a spatial extent of a few square centimeters and a thermal contrast of 3° C. would be flagged as a possible threat. Performing such analysis based on a sifting of physical parameters such as temperature is an easier proposition compared to computer vision on a complicated higher resolution image.

In the exemplary embodiment, thermal detection system 102 includes a fast, walk-through mode of operation, in which sensor array 112 includes a plurality of sensors 110 that are stacked vertically and aimed at a path diagonal to the path of a passenger entering inspection system 102. During transit into inspection system 100, the passenger would effectively sweep past array 112, “painting” out a thermal profile of a horizontal distribution of temperatures on the body, as shown in FIG. 3. Alternatively, array 112 may gather thermal profile data for use in generating a two-dimensional temperature map or a three-dimensional temperature map. In this manner, sensors 110 are physically and operationally independent from the sensors used by QR system 104 and trace sensor 106.

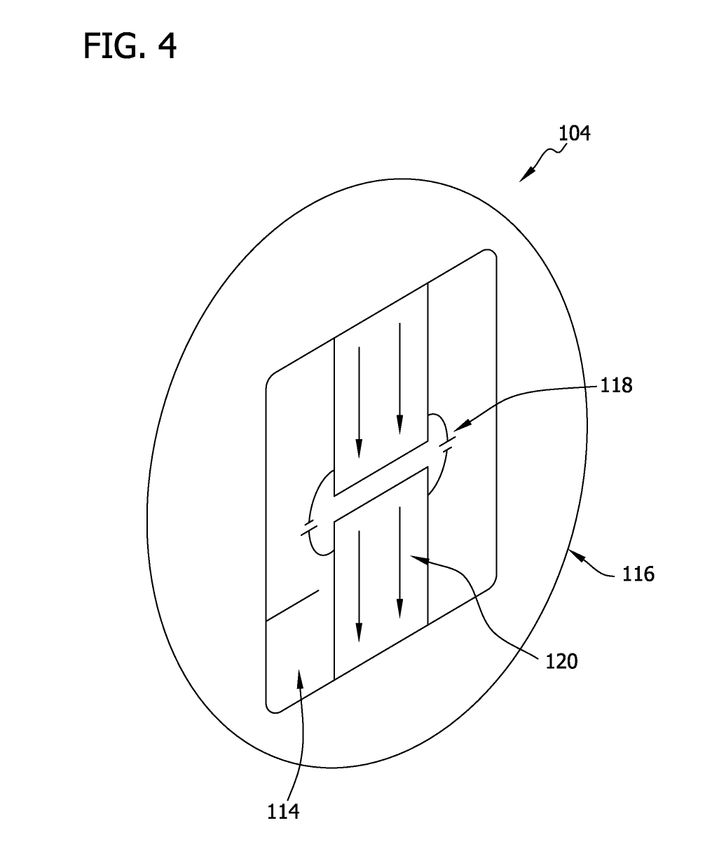

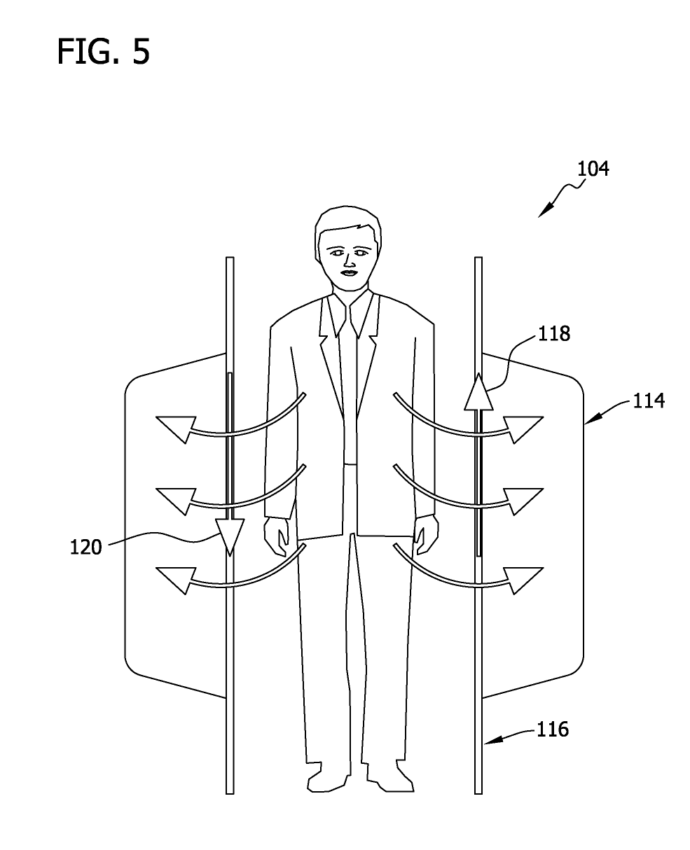

FIG. 4 is a top view of QR system 104, and FIG. 5 is a side view of QR system 104. In the exemplary embodiment, QR system 104 is configured to automatically determine the presence of bulk threat materials. For example, QR system 104 is configured to find articles composed of “sticky” compositions and/or molecules that have very low vapor pressures. QR system 104 may also be configured to find materials hidden inside the passenger's body, in between the legs, or flattened against the body surface, in a manner that makes them difficult to identify with thermal detection system 102 (shown in FIGS. 2 and 3) because of insufficient difference in temperature. It should be understood that most articles suspected of being contraband may be reasonably assumed to be within a few degrees Centigrade of body temperature. As such, in the exemplary embodiment, QR system 104 is tuned, configured, and/or adapted to enhance identification of QR-detectable articles. The tuning, configuring, and/or adaptation includes, for example, enabling QR system 104 to operate in a narrow temperature range around the typical human body temperature, to operate without direct human control, operating within a geometric range that is limited to approximately the torso of passengers, and enabling QR system 104 to also detect metal or metallic objects.

In some embodiments, QR system 104 is configured to operate over a narrow range of temperatures, such as the range of temperatures of body-borne contraband, contraband hidden in the underwear or other areas in close thermal proximity to the passenger's body, or materials flattened against the passenger's body. It should be understood that the frequency of operation for QR system 104 is a function of the temperature of operation. Earlier QR systems were generally operated in a range centered on the ambient temperature of the operating environment. In the exemplary embodiment, QR system 104 is operated at a range of frequencies corresponding only to the range of temperatures associated with body and near-body bound articles. Moreover, operating over a narrower range of temperatures allows lower radio frequency field strength to be used in the excitation used to stimulate QR signals, as well as a narrower range of detection frequencies, which implies a lower noise bandwidth that results in improved detection performance. This provides synergy between QR system 104 and thermal detection system 102. In the exemplary embodiment, QR system 104 is operated over a range of temperatures at or near body temperature, including a range from approximately 32° C. to approximately 37° C.

In some embodiments, QR system 104 is configured to automatically operate without generating images. Rather, QR system 104 is configured to determine if a signal level attributable to an item suspected of being contraband crosses an established threshold. Moreover, in some embodiments, QR system 104 is configured to operate over a geometric range. For example, in the exemplary embodiment, the geometric range is limited to the passenger's torso, where contraband may be more easily hidden internally, obscured by concealing in undergarments, and/or hidden in a manner to resemble body anatomy. Furthermore, in some embodiments, QR system 104 includes an electromagnetic modality (not shown), such as a metal sensor configured to find metal weapons and/or metallic materials that might interfere with the operation of any other sensor described herein and that might be indicative of efforts to conceal threats.

In the exemplary embodiment, QR system 104 includes one or more sensors 114 positioned at a height expected to approximate the height of the abdomen of an average passenger. Moreover, a height of sensors 114 is adjustable to match the abdominal height of each passenger. In certain embodiments, the abdominal height is defined as a distance that extends approximately between the passenger's knee and chest. Because passenger screening often takes place in an environment with significant radio frequency interference, in some embodiments shielding 116 is positioned around QR system 104 to increase a signal-to-noise ratio. Shielding 116 may include conductive plates that connect a floor (not shown) to a ceiling (not shown) of inspection system 100. During the scanning process, each sensor 114 provides radio frequency excitation signals and picks up resulting signals that indicate the presence of contraband. For example, each sensor 114 provides radio frequency excitation signals at a frequency generally corresponding to a predetermined, characteristic NQR frequency of the target contraband substance. Each sensor 114 may also act as a pick-up coil to detect any resulting QR signals emanating from contraband concealed by a passenger. These signals may be communicated to any suitable computing device for processing and analysis.

Each sensor 114 includes two anti-symmetric current branches 118 and 120. The term “anti-symmetric” refers to the condition in which current flows through current branch 118 of sensor 114 in a direction substantially opposite to the direction of current flow through current branch 120, as indicated by the arrows in FIG. 5. The anti-symmetric current flow produces counter-directed magnetic fields that are well-attenuated and have a topography that is especially suited for examination of the proximately positioned abdominal area of a passenger, including body cavities. In some embodiments, sensors 114 are located between zero and 180 degrees apart from each other (not shown) in inspection system 100. Such an arrangement facilitates reducing a susceptibility of QR system 104 to radio frequency interference and targeting a sensitivity of QR system 104 to the abdominal region of interest. Additionally or alternatively, in some embodiments, one or more sensors 114 have current branch 118 and current branch 120 located closer together than in traditional inductive sensors to create a smaller, more locally focused coil system that has a higher signal to noise ratio than traditional inductive sensors.

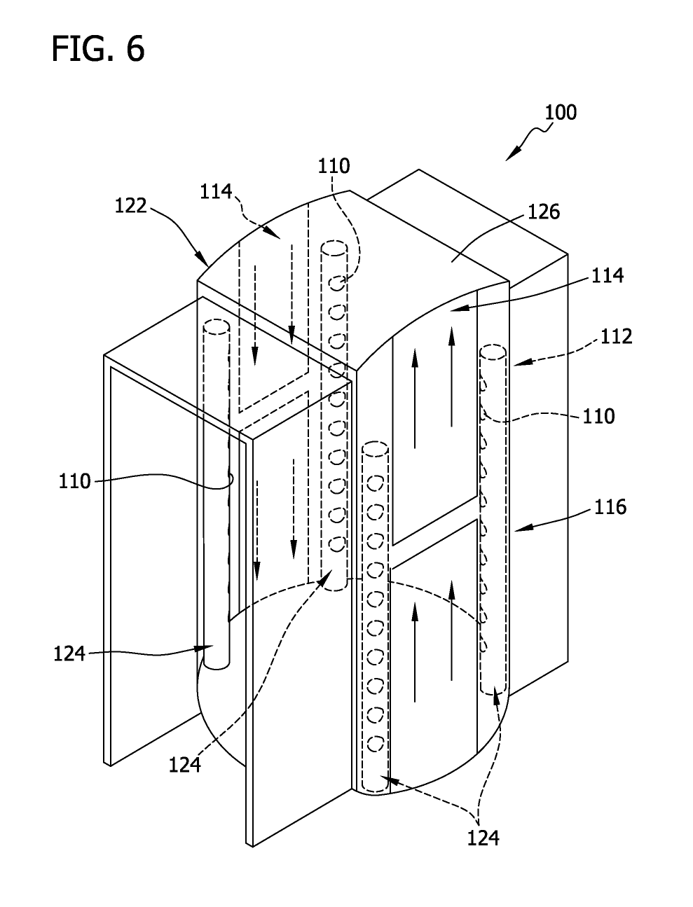

FIG. 6 is a perspective view of inspection system 100. In the exemplary embodiment, inspection system 100 is in the form of a walk-through portal 122. Each corner of portal 122 includes a pillar 124 in which sensor array 112 is stacked vertically and aimed at a path diagonal to the path of a passenger entering inspection system 100. Alternatively, each pillar 124 may include a single sensor 110 that is movable in a vertical direction. In the exemplary embodiment, QR sensors 114 are positioned within inspection system 100 to facilitate gathering data as a passenger walks through portal 122. Sensors 110 or sensor arrays 112 are similarly positioned within inspection system 100 to facilitate gathering data as a passenger walks through portal 122.

Moreover, in the exemplary embodiment, trace sensor 106 is positioned in a top portion 126 of portal 122. Trace sensor 106 is configured to detect explosives and/or other contraband chemicals. Moreover, trace sensor 106 provides detection coverage for non-sticky compounds that may not be identified by QR system 104. Furthermore, trace sensor 106 is configured to detect higher vapor pressure contraband that may not be detected by QR system 104. In the exemplary embodiment, trace sensor 106 is an ion trap mobility spectrometer (ITMS). In alternative embodiments, trace sensor 106 may also include a mass spectrometer and/or one or more tunable infrared lasers for detecting absorption lines characteristic of explosives or contraband chemicals, and/or an ion trap mobility spectrometer. Moreover, in the exemplary embodiment, trace sensor 106 is tuned and adapted to maximize its ability to quickly deliver the identification of the preferred articles. For example, trace sensor 106 may be optimized to find the non-sticky materials and QR system 104 may be tuned to find those materials that are at or near body temperature and thermal detection system 102 is configured to find those materials that are not at thermal equilibrium with the passenger's body.

Furthermore, trace sensor 106 may be configured to operate with a configuration targeted to finding materials that are in close thermal contact with the passenger's body, either internally, in undergarments, or flattened against the passenger's body. In some embodiments, trace sensor 106 is optimized to find vapor-phase molecules as opposed to particles. In such embodiments, there are no puffers used to dislodge particles. With this adaptation, trace sensor 106 is less prone to contamination events and adverse reactions from subjects are minimized. Operating trace sensor 106 without a puffer is simpler, since with the puffer removed, there is more space for thermal detection system 102 and QR system 104. Finally, operating trace sensor 106 in vapor phase mode may allow extended targets to be detected as the collection system is simplified, resulting in less deterioration or decomposition of target molecules within portal 122.

During operation, a passenger enters portal 122 and is inspected using thermal detection system 102, QR system 104, and trace sensor 106. In some embodiments, the passenger is inspected by systems 102 and 104 and sensor 106 approximately simultaneously. In other embodiments, the passenger is sequentially inspected by systems 102 and 104 and sensor 106. The order of inspection of the passenger may be controlled by controller 108 (shown in FIG. 1).

During the inspection, thermal detection system 102 collects thermal imaging data of the passenger via sensors 110 or sensor arrays 112. Specifically, thermal detection system 102 is configured to distinguish thermal properties of contraband from thermal properties of the passenger in order to discern bulk articles that are not in thermal equilibrium with the passenger's body, such as articles that are not thermally bound to the body. Thermal detection system 102 transmits the thermal detection data to controller 108.

Moreover, QR system 104 is configured to find materials hidden inside the passenger's body, in between the legs, or flattened against the body surface, in a manner that makes them difficult to identify with thermal detection system 102 because of insufficient difference in temperature. For example, each sensor 114 (shown in FIGS. 4 and 5) provides radio frequency excitation signals and picks up resulting signals that indicate the presence of contraband. More specifically, each sensor 114 provides radio frequency excitation signals at a frequency generally corresponding to a predetermined, characteristic NQR frequency of the target contraband substance. Each sensor 114 may also act as a pick-up coil to detect any resulting QR signals emanating from contraband concealed by a passenger and QR system 104 transmits these signals to controller 108.

In addition, trace sensor 106 receives vapor-phase molecules and analyzes the molecules to determine a probable chemical composition of an object or contraband from which the molecules originated. Trace sensor 106 transmits the chemical composition data to controller 108.

Based on the thermal detection data, QR signals, and/or chemical composition data, controller 108 determines whether the passenger holds an item of contraband. For example, controller 108 determines whether thermal detection data indicates the presence of an object that has a temperature sufficiently different from the temperature of the passenger's body. Moreover, controller 108 determines whether QR signals received from the object meet or exceed any of a plurality of predetermined signal levels that are each associated with a known contraband substance. Based on one or more of the determinations relating to the trace detection data, the thermal detection data, and the QR signals, controller 108 determines whether a detected item is contraband. Alternatively, controller 108 determines whether there is a sufficiently high probability that the detected item is contraband. In such cases, controller 108 may then generate an image based on the thermal detection data, QR signals, and/or chemical composition data for viewing and analysis by security personnel. For example, controller 108 may generate a single image based on the thermal detection data and the QR signals, and may overlay the chemical composition data as text, for example. Alternatively, controller 108 may generate multiple images, such as a first image based on the thermal detection data and a second image based on the QR signals, and may overlay the chemical composition data as text on either or both of the first and second images. However, as described above, controller 108 may not generate an image but, rather, may simply raise an alarm that prompts security personnel to inspect the passenger if one or more of thermal detection data, QR signals, and/or chemical composition data indicate contraband.

Exemplary embodiments of inspections systems for use in inspecting a passenger for contraband are described above in detail. The systems are not limited to the specific embodiments described herein but, rather, operations and/or components of the system may be utilized independently and separately from other operations and/or components described herein. Further, the described operations and/or components may also be defined in, or used in combination with, other systems, methods, and/or apparatus, and are not limited to practice with only the systems described herein.

A computer or controller, such as those described herein, includes at least one processor or processing unit and a system memory. The computer or controller typically has at least some form of computer readable media. By way of example and not limitation, computer readable media include computer storage media and communication media. Computer storage media include volatile and nonvolatile, removable and non-removable media implemented in any method or technology for storage of information such as computer readable instructions, data structures, program modules, or other data. Communication media typically embody computer readable instructions, data structures, program modules, or other data in a modulated data signal such as a carrier wave or other transport mechanism and include any information delivery media. Those skilled in the art are familiar with the modulated data signal, which has one or more of its characteristics set or changed in such a manner as to encode information in the signal. Combinations of any of the above are also included within the scope of computer readable media.

Although the present invention is described in connection with an exemplary passenger inspection system environment, embodiments of the invention are operational with numerous other general purpose or special purpose inspection system environments or configurations. The inspection system environment is not intended to suggest any limitation as to the scope of use or functionality of any aspect of the invention. Moreover, the inspection system environment should not be interpreted as having any dependency or requirement relating to any one or combination of components illustrated in the exemplary operating environment. Examples of well known inspection systems, environments, and/or configurations that may be suitable for use with aspects of the invention include, but are not limited to, personal computers, server computers, hand-held or laptop devices, multiprocessor systems, microprocessor-based systems, set top boxes, programmable consumer electronics, mobile telephones, network PCs, minicomputers, mainframe computers, distributed computing environments that include any of the above systems or devices, and the like.

Embodiments of the invention may be described in the general context of computer-executable instructions, such as program components or modules, executed by one or more computers or other devices. Aspects of the invention may be implemented with any number and organization of components or modules. For example, aspects of the invention are not limited to the specific computer-executable instructions or the specific components or modules illustrated in the figures and described herein. Alternative embodiments of the invention may include different computer-executable instructions or components having more or less functionality than illustrated and described herein.

The order of execution or performance of the operations in the embodiments of the invention illustrated and described herein is not essential, unless otherwise specified. That is, the operations may be performed in any order, unless otherwise specified, and embodiments of the invention may include additional or fewer operations than those disclosed herein. For example, it is contemplated that executing or performing a particular operation before, contemporaneously with, or after another operation is within the scope of aspects of the invention.

In some embodiments, the term “processor” refers generally to any programmable system including systems and microcontrollers, reduced instruction set circuits (RISC), application specific integrated circuits (ASIC), programmable logic circuits (PLC), and any other circuit or processor capable of executing the functions described herein. The above examples are exemplary only, and thus are not intended to limit in any way the definition and/or meaning of the term processor.

In some embodiments, the term “database” refers generally to any collection of data including hierarchical databases, relational databases, flat file databases, object-relational databases, object oriented databases, and any other structured collection of records or data that is stored in a computer system. The above examples are exemplary only, and thus are not intended to limit in any way the definition and/or meaning of the term database. Examples of databases include, but are not limited to only including, Oracle® Database, MySQL, IBM® DB2, Microsoft® SQL Server, Sybase®, and PostgreSQL. However, any database may be used that enables the systems and methods described herein. (Oracle is a registered trademark of Oracle Corporation, Redwood Shores, Calif.; IBM is a registered trademark of International Business Machines Corporation, Armonk, N.Y.; Microsoft is a registered trademark of Microsoft Corporation, Redmond, Wash.; and Sybase is a registered trademark of Sybase, Dublin, Calif.)

When introducing elements of aspects of the invention or embodiments thereof, the articles “a,” “an,” “the,” and “said” are intended to mean that there are one or more of the elements. The terms “comprising,” including,” and “having” are intended to be inclusive and mean that there may be additional elements other than the listed elements.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A method for detecting objects foreign to a human body using an inspecting system including a controller, a thermal detector, and a quadrapole resonance (QR) device, said method comprising:
obtaining thermal imaging data from the thermal detector;
transmitting an excitation signal by the QR device; and
determining if a foreign object is present based on the thermal imaging data and whether a resulting signal emanating from a material excited by the excitation signal is received by the QR device.

2. A method in accordance with claim 1 further comprising receiving vapor-phase molecule information from a trace sensor.

3. A method in accordance with claim 2 further comprising determining a probable composition of an object foreign to the body from the received vapor-phase molecule information.

4. A method in accordance with claim 1 wherein determining if a foreign object is present further comprises determining if the resulting signal is at or above a pre-determined threshold.

5. A method in accordance with claim 1 wherein determining if a foreign object is present further comprises determining if a temperature difference of at least 3° C. exists between at least two objects in the obtained thermal imaging data.

6. A method in accordance with claim 5 wherein determining if a temperature difference of at least 3° C. further comprises determining if the at least two objects have a spatial resolution of at least 2 centimeters.

7. A method in accordance with claim 1 wherein transmitting an excitation signal by the QR device further comprises transmitting an excitation signal that corresponds to a predefined temperature range.

8. A method in accordance with claim 1 further comprising detecting metal by the QR device.

9. A method in accordance with claim 1 wherein transmitting an excitation signal by the QR device further comprises transmitting a radio frequency excitation signal by the QR device.

10. A method in accordance with claim 1 further comprising producing, by the controller, an image of a determined foreign object and not a human body.

11. A system for detecting objects foreign to a human body, said system comprising:
a thermal detector configured to obtain thermal imaging data;
a quadrapole resonance (QR) device configured to transmit an excitation signal and receive a resulting signal emanating from a material excited by the excitation signal; and
a controller configured to determine if a foreign object is present based on the thermal imaging data and the excitation signal.

12. A system in accordance with claim 11 further comprising a trace sensor configured to receive vapor-phase molecule information.

13. A system in accordance with claim 12 wherein said trace sensor is further configured to determine a probable composition of an object foreign to the body from the received vapor-phase molecule information.

14. A system in accordance with claim 11 wherein said QR device is further configured to determine if a resulting signal is at or above a pre-determined threshold.

15. A system in accordance with claim 11 wherein said thermal detector is further configured to determine if a temperature difference of at least 3° C. exists between at least two objects in obtained thermal imaging data.

16. A system in accordance with claim 15 wherein said thermal detector is further configured to determine if the at least two objects having a temperature difference of at least 3° C. has a spatial resolution of at least 2 centimeters.

17. A system in accordance with claim 11 wherein said QR device is further configured to transmit an excitation signal that corresponds to a predefined temperature range.

18. A system in accordance with claim 11 wherein said QR device is further configured to transmit a radio frequency excitation signal.

19. One or more computer-readable storage media having computer-executable instructions embodied thereon, wherein when executed by at least one processor, the computer-executable instructions cause at least one processor to:
obtain thermal imaging data from a thermal detector;
transmit an excitation signal by a QR device; and
determine if a foreign object is present based on the thermal imaging data and whether a resulting signal emanating from a material excited by the excitation signal is received by the QR device.

20. One or more computer-readable storage media in accordance with claim 19 wherein when executed by the processor, the computer-executable instructions further cause the processor to receive vapor-phase molecule information from a trace sensor.
